(19) United States
(12) Patent Application Publication
(10) Pub. No.: US 2008/0164945 A1
(43) Pub. Date: Jul. 10, 2008

(54) Simple operational amplifiers circuit and alternative circuit of latch circuit

(76) Inventor: Ping Fong Yang, Tainan City (TW)

Correspondence Address: TROXELL LAW OFFICE PLLC;SUITE 1404, 5205 LEESBURG PIKE, FALLS CHURCH, VA, 22041, US

(21) Appl. No.: 11/650,563

(22) Filed: Jan. 8, 2007

(51) Int. Cl. H03F 3/45

(52) U.S. Cl. 330/253

(57) ABSTRACT

A simple operational amplifier (OP amp) and an alternative circuit of a latch circuit constructed by a Bipolar Junction Transistor (BJT) or a Metal-Oxide Semiconductor Field Effect Transistor (MOSFET) are provided to obtain a higher output ability (higher input/output voltage and output circuit).

### CROSS-REFERENCES TO RELATED APPLICATIONS

Not Applicable

### STATEMENT REGARDING FEDERALLY SPONSORED RESEARCH OR DEVELOPMENT

Not Applicable

### DESCRIPTION

### Field of the Invention

The invention relates to a simple operational amplifier (OP amp) and an alternative circuit of a latch circuit, and more particularly to a simple OP amp circuit and a latch circuit alternative circuit constructed by a Bipolar Junction Transistor (BJT) or a Metal-Oxide Semiconductor Field Effect Transistor (MOSFET) to obtain higher output ability (higher input/output voltage and output circuit).

### BACKGROUND OF THE INVENTION

Operational amplifiers are well used in various electrical products. Generally speaking, the OP amplifiers provided by the Integrated Circuit (IC) only have limited input/output voltages and currents. As a result, an extra auxiliary circuit must be provided in some applications which need higher input voltage. However, such an extra auxiliary circuit will increase the cost. Therefore, a series of simple OP amp circuits constructed by components such as BJTs, MOSFETs, etc. . . . which can bear higher input voltages are provided by the invention.

On the other hand, the latch circuits are also well-used in various electric products. Commonly, the usage of the latch circuit constructed by the logic IC is still limited in the input/output voltage/current. Therefore, in a real application, an extra circuit is needed for increasing the output ability and providing a higher bearing ability for the input voltage. Apparently, the cost will be remarkably increased by the usage of the extra circuit.

It is desirable to provide an alternative circuit composed by components such as OP, comparers, BJTs, MOSFETs, etc. . . . which have higher output voltages/currents and higher bearing abilities to the input voltages. Such a technical scheme is surely practical and economic. The invention provides not only a series of simple OP amp circuits, but also alternative circuits of latch circuits constructed by components such as the comparers, BJTs, MOSFETs, etc.

### SUMMARY OF THE INVENTION

Therefore, the present invention provides a simple OP amp circuit constructed by a Bipolar Junction Transistor (BJT) or a Metal-Oxide Semiconductor Field Effect Transistor (MOSFET) to obtain higher output ability (higher input/output voltage and output circuit).

The present invention also provides a latch circuit alternative circuit constructed by a Bipolar Junction Transistor (BJT) or a Metal-Oxide Semiconductor Field Effect Transistor (MOSFET) to obtain higher output ability (higher input/output voltage and output circuit).

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 graphically illustrates a circuit diagram of a simple OP amp according to one embodiment of the invention;

FIG. 2 graphically illustrates another circuit diagram of a simple OP amp according to one embodiment of the invention;

FIG. 3 graphically illustrates still another circuit diagram of a simple OP amp according to one embodiment of the invention;

FIG. 4 graphically illustrates a further circuit diagram of a simple OP amp according to one embodiment of the invention;

FIG. 5 graphically illustrates still further circuit diagram of a simple OP amp according to one embodiment of the invention;

FIG. 6 graphically illustrates still another circuit diagram of a simple OP amp according to one embodiment of the invention;

FIG. 7 graphically illustrates another circuit diagram of a simple OP amp according to one embodiment of the invention;

FIG. 8 graphically illustrates still further circuit diagram of a simple OP amp according to one embodiment of the invention;

FIG. 9 graphically illustrates still another circuit diagram of a simple OP amp according to one embodiment of the invention;

FIG. 10 graphically illustrates a further circuit diagram of a simple OP amp according to one embodiment of the invention;

FIG. 11 graphically illustrates still further circuit diagram of a simple OP amp according

FIG. 12 graphically illustrates still another circuit diagram of a simple OP amp according to one embodiment of the invention; to one embodiment of the invention;

FIG. 13 graphically illustrates a circuit diagram of an alternative circuit of a latch circuit according to one embodiment of the invention;

FIG. 14 graphically illustrates another circuit diagram of an alternative circuit of a latch circuit according to one embodiment of the invention; and

FIG. 15 graphically illustrates still circuit diagram of an alternative circuit of a latch circuit according to one embodiment of the invention.

### DETAILED DESCRIPTION OF SOME EMBODIMENTS

The invention provides a series of simple OP amp circuits constructed by BJTs, MOSFETs, and a plurality of latch circuit alternative circuits. Each one of the series of circuits can replace the OP amp. The series of circuit includes three embodiments as described below:

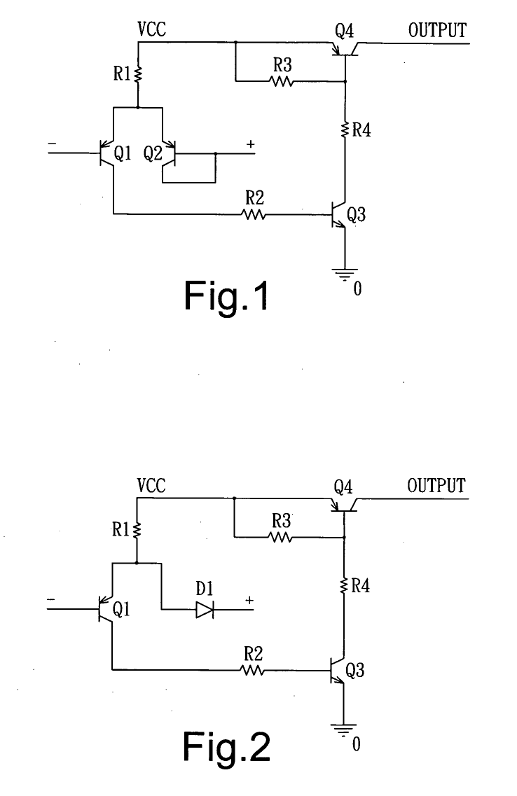

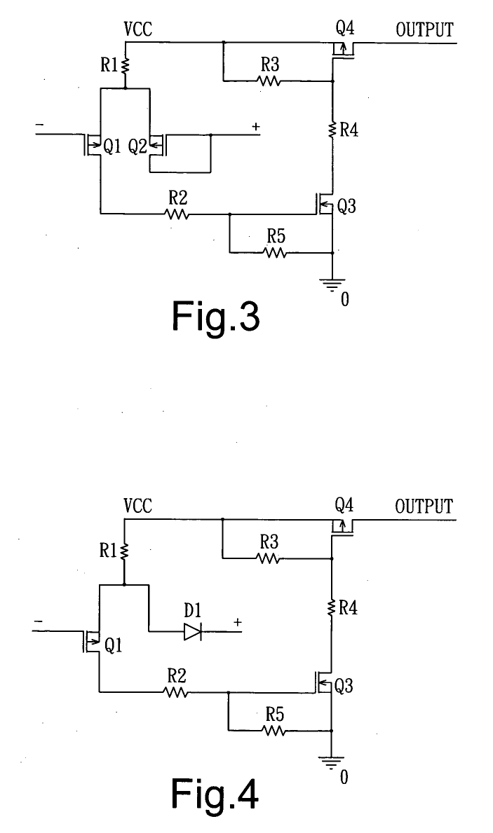

The First Embodiment: As shown in FIG. 1, several BJTs construct a simple OP amp circuit. Now refer to FIG. 2. It is shown that the component Q2 can be replaced by a diode. FIG. 3 illustrates that the BJTs are replaced by MOSFETs. As shown in FIG. 4, the component Q2 can also be replaced by a diode.

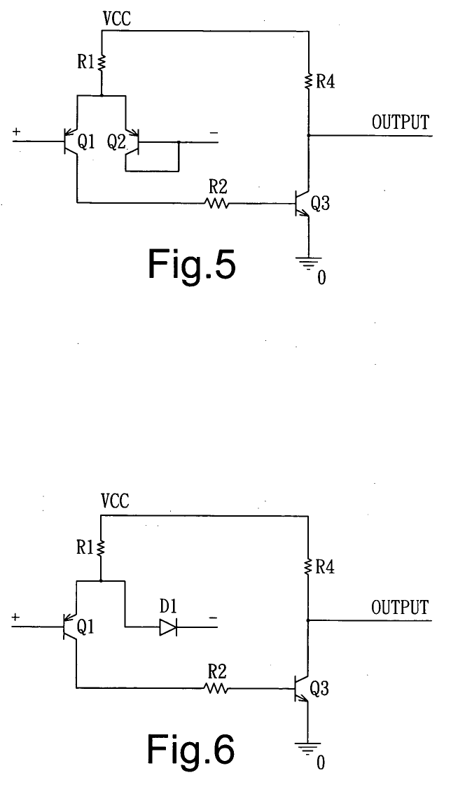

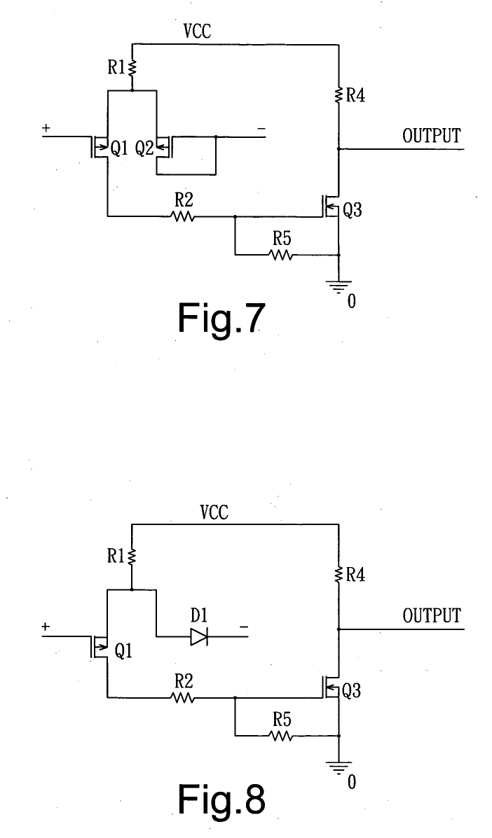

The Second Embodiment: As shown in FIG. 5, several BJTs construct a simple OP amp circuit. Now refer to FIG. 6. It is shown that the component Q2 can be replaced by a diode. FIG. 7 illustrates that the BJTs are replaced by MOSFETs. As shown in FIG. 8, the component Q2 can also be replaced by a diode.

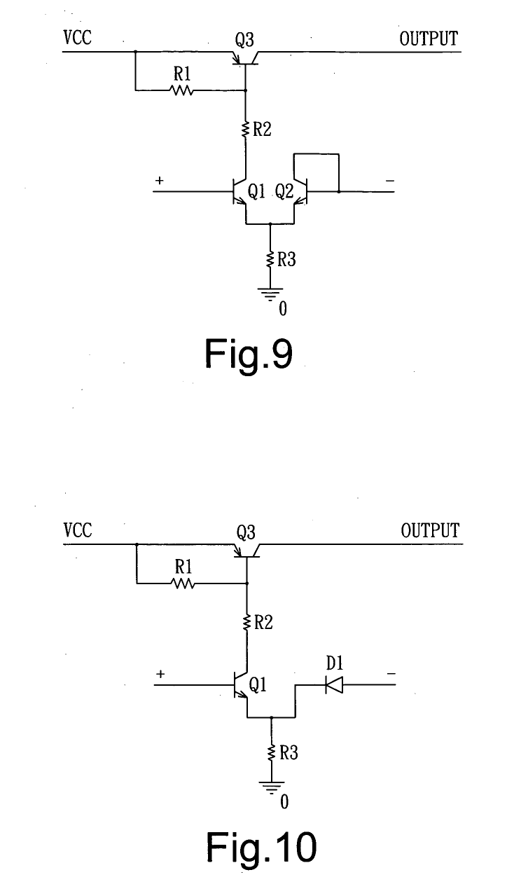

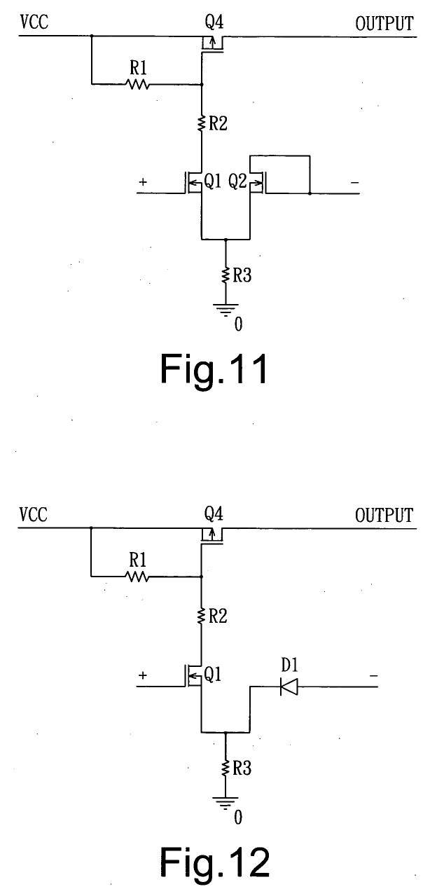

The Third Embodiment: As shown in FIG. 9, several BJTs construct a simple OP amp circuit. Now refer to FIG. 10. It is shown that the component Q2 can be replaced by a diode. FIG. 11 illustrates that the BJTs are replaced by MOSFETs. As shown in FIG. 12, the component Q2 can also be replaced by a diode.

The invention breaks through the conventional technical method for designing a latch circuit. A series of circuits is provided to take over the function of the latch circuit and provide higher output voltages/currents and higher input bearing voltage.

The invention further includes a series of latch circuit alternative circuits. Each of the alternative circuits can take over the function of the latch circuits. There are three embodiments as described below:

The latch circuit alternative circuits of the invention use the feedback circuit to preserve the original signal statuses (LOW or HIGH) of the signal input terminal. Such signal status preservations of input terminals will achieve the function which is used to be done by the latch circuit in the conventional device. However, the feedback circuits are constructed by normal components, and the selection of components can be varied according to different needs of various circuits.

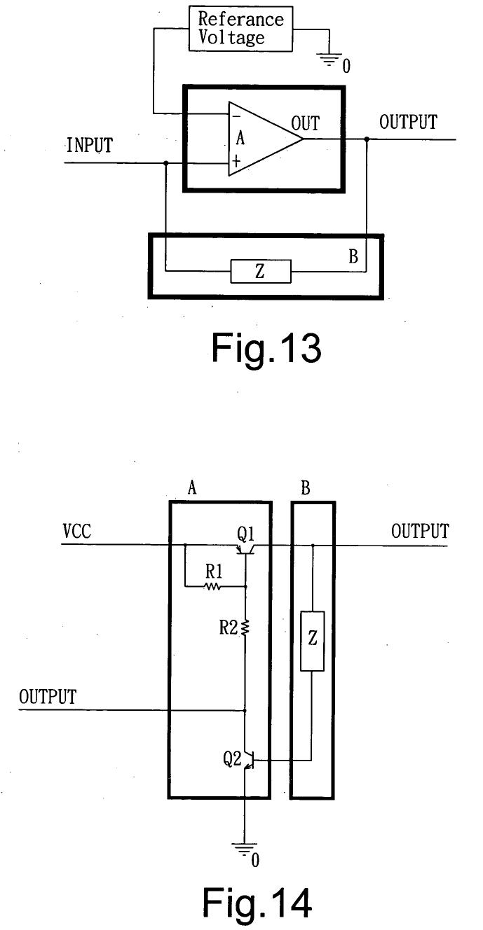

The Fourth Embodiment: As shown in FIG. 13, a latch circuit is constructed by an OP or a comparer. Block A illustrates a circuit of an OP or a comparer, while block B indicates the circuit of a feedback circuit constructed by another component.

When the input signal is higher than the reference voltage OP or the reference voltage of the negative terminal (−) of the comparer, the status of the input terminal is HIGH (the largest output voltage of the 0 or the comparer). The reference voltage can be provided by a common reference voltage component or a resistance voltage divider.

When the input signal on the input terminal is removed, the signal of the output terminal will be transmitted through the feedback circuit B to the input terminal so as to preserve the status of the input terminal (HIGH) and keep the status of the output terminal (HIGH) unchanged.

When the input signal is lower than the reference voltage OP, the reference voltage of the negative terminal (−) of the comparer, or the resistance voltage divider, the status of the input terminal is LOW.

When the input signal on the input terminal is removed, the signal of the output terminal will be transmitted through the feedback circuit B to the input terminal so as to preserve the original status of the input terminal (LOW), and keep the status of the output terminal (LOW) unchanged. Accordingly, a latch operation is achieved.

The Fifth Embodiment: As shown in FIG. 14, block A indicates an amplifier circuit constructed by switch components, wherein components Q1 and Q2 may be a BJT or a MOSFET, respectively. The circuit block B is a feedback circuit constructed by another component.

When the voltage of the input terminal is higher than the threshold voltage, the component Q1 will be turned on, the component Q2 will be turned on and the status of the input terminal will be HIGH (VCC). When the signal of the input terminal is removed, the signal of the output terminal will be transmitted through feedback circuit B to the input terminal so as to preserve the original status of the input terminal (HIGH) and keep the status of the output terminal (HIGH) unchanged.

When the input signal is lower than the internal reference voltage, the status of the output terminal is LOW. While removing the input signal on the input terminal, the signal of the output terminal will be transmitted through the feedback circuit B to the input terminal to retain the input signal's original status (LOW) and preserve the status of the output terminal (LOW). Accordingly, a latch operation is achieved.

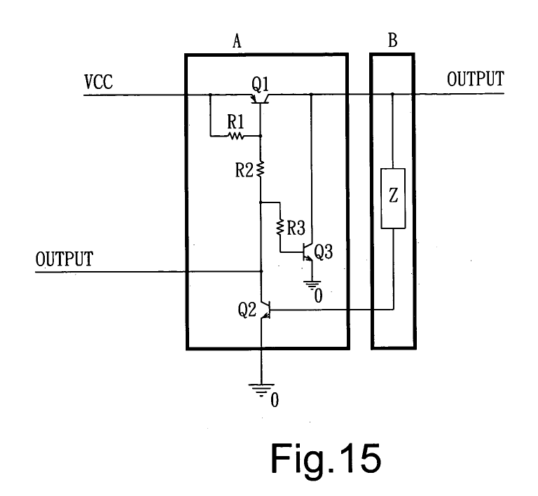

The Sixth Embodiment: As shown in FIG. 15, the circuit block A is an amplifier circuit constructed by switch components and includes a discharging loop. The components Q1, Q2, and Q3 may be a BJT or a MOSFET, respectively. The circuit block B is a feedback circuit constructed by another component.

When the voltage of the input terminal is higher than the threshold voltage of the component Q1, the component Q1 will be turned on and then the component Q2 will be turned on and the status of the output terminal will be HIGH (VCC). When the component Q1 is turned on, the component Q3 will be turned off, and the feedback circuit will not operate.

When the input signal of the input terminal is removed, the signal of the output terminal will be transferred through the feedback circuit B to the input terminal to maintain the input terminal in its original status (HIGH), and preserve the status of the output terminal (HIGH).

When the voltage of the input terminal is lower than the threshold voltage of the component Q1, the component Q1 will be turned off and then the component Q3 (discharge loop) will be turned on. Then, the component Q2 will be turned off and the status of the output terminal will be LOW. While removing the input signal on the input terminal, the signal of the output terminal will be transmitted from the feedback circuit B to the input terminal to remain the input signal in an original status (LOW) and preserve the status of the output terminal (LOW). Accordingly, a latch operation is achieved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A simple OP amp circuit of a series of simple OP amp circuits, each of which can perform an OP amp function, wherein
a first one of said series of simple OP amp circuit is shown in FIG. 1, which includes a plurality of bipolar junction transistors (BJTs) to perform an OP amp function;
a second one of said series of simple OP amp circuit is as shown in FIG. 2, wherein a diode takes place of the component Q2 shown in FIG. 1 so that said OP amp function can still be performed;
a third one of said series of simple OP amp circuits is shown in FIG. 3, which includes a plurality of Metal-Oxide Semiconductor Field Effect Transistor (MOSFETs) to perform said OP amp function; and
a fourth one of said series of simple is shown in FIG. 4, wherein a diode takes place of the component Q2 shown in FIG. 3 so that said OP amp function can still be performed.

2. A simple OP amp circuit according to claim 1, wherein
a fifth one of said series of simple OP amp circuit is shown in FIG. 5, which includes a plurality of bipolar junction transistors (BJTs) to achieve said OP amp function;
a sixth one of said series of simple OP amp circuit is shown in FIG. 6, wherein a diode takes place of the component Q2 shown in FIG. 5 so that said OP amp function can still be performed;
a seventh one of said series of simple OP amp circuits is shown in FIG. 7, which includes a plurality of Metal-Oxide Semiconductor Field Effect Transistor (MOSFETs) to perform an OP amp function; and
an eighth one of said series of simple is shown in FIG. 8, wherein a diode takes place of the component Q2 shown in FIG. 7 so that said OP amp function can still be performed.

3. A simple OP amp circuit according to claim 1, wherein
a ninth one of said series of simple OP amp circuit is shown in FIG. 9, which includes a plurality of bipolar junction transistors (BJTs) to perform said OP amp function;
a tenth one of said series of simple OP amp circuit is shown in FIG. 10, wherein a diode takes place of the component Q2 shown in FIG. 9 so that said OP amp function can still be performed;
a third one of said series of simple OP amp circuits is shown in FIG. 11, which includes a plurality of Metal-Oxide Semiconductor Field Effect Transistor (MOSFETs) to perform said OP amp function; and
a fourth one of said series of simple is shown in FIG. 12, wherein a diode takes place of the component Q2 shown in FIG. 11 so that said OP amp function can still be performed.

4. A latch circuit alternative circuit as shown in FIG. 13, comprising a latch circuit constructed by an OP or a comparer, wherein circuit block A is a circuit of an OP or a comparer, and circuit block B is a feedback circuit constructed by a component.

5. A latch circuit alternative circuit according to claim 4, wherein, as shown in FIG. 14, the circuit block A is a simple OP amp circuit wherein the component Q1 and the component Q2 are selected from a BJT and a MOSFET, respectively, and the circuit block B is a feedback circuit constructed by a component.

6. A latch circuit alternative circuit according to claim 4, wherein, as shown in FIG. 15, the circuit block A is a simple OP amp circuit comprising a discharging loop wherein the components Q1, Q2, and Q3 are selected from a BJT and a MOSFET, respectively, and the circuit block B is a feedback circuit constructed by a component.
